(19) United States
(12) Patent Application Publication
(10) Pub. No.: US 2010/0146356 A1
(43) Pub. Date: Jun. 10, 2010

(54) WIRELESS SENSOR NODE

(75) Inventors: Tae-joon PARK, Daejeon-si (KR); Ho-yong Kang, Daejeon-si (KR); Nae-soo Kim, Daejeon-si (KR); Cheol-sig Pyo, Daejeon-si (KR); Jong-suk Chae, Daejeon-si (KR)

Correspondence Address: STAAS & HALSEY LLP, SUITE 700, 1201 NEW YORK AVENUE, N.W., WASHINGTON, DC, 20005, US

(73) Assignee: ELECTRONICS AND TELECOMMUNICATIONS RESEARCH INSTITUTE, Daejeon-si (KR)

(21) Appl. No.: 12/630,354

(22) Filed: Dec. 3, 2009

(30) Foreign Application Priority Data
Dec. 5, 2008 (KR) 10-2008-0123117
Jun. 12, 2009 (KR) 10-2008-0052420

(51) Int. Cl. H04L 1/18; H04L 12/28; H03M 13/09; G06F 11/10; G06F 11/14

(52) U.S. Cl. 714/749; 370/254; 714/807; 714/E11.032; 714/E11.113

(57) ABSTRACT

A wireless sensor node is provided which is divided into functional modules on a function basis and operates the functional modules to cooperatively perform its individual functions. The wireless sensor node includes a wireless transceiver to wirelessly communicate with a control node; a primary configuration unit to set a node identification address in communication with a control node; a secondary configuration unit to use the node identification address to register with the control node and set an address for communication which is assigned by the control node; a basic power supply to supply power to modules for communication and sensor control; functional modules to perform data processing and sensor control; and a functional module activator to activate the functional modules according to a type of received data or an operation for data transmission.

### CROSS REFERENCE TO RELATED APPLICATION

This application claims the benefit under 35 U.S.C. §119(a) of Korean Patent Applications No. 10-2008-0123117, filed on Dec. 5, 2008 and No. 10-2009-0052420, filed on Jun. 12, 2009, the disclosure of which is incorporated by reference in its entirety for all purposes.

### BACKGROUND

1. Field

The following description relates to a wireless sensor network, and more particularly, to a wireless sensor node which is divided into functional modules on a function basis and operates the functional modules to cooperatively perform its individual functions.

2. Description of the Related Art

A wireless sensor network (WSN) is a wireless network consisting of spatially distributed autonomous devices using sensors having computing and wireless communication capabilities to cooperatively monitor physical or environmental conditions at different locations. The development of wireless sensor networks was originally motivated by military applications such as battlefield surveillance. However, the wireless sensor network is fundamental to a ubiquitous network and is now used in many industrial and civilian application areas, including industrial process monitoring and control, machine health monitoring, environment and habitat monitoring, healthcare applications, telematics, home automation, and traffic control.

In general, the wireless sensor node includes a sensor, an MCU and a wireless communication module, which are separated from each other or integrated into a signal entity. The sensor node needs to be equipped with software to drive the MCU and perform its application functions.

In this case, however, it is difficult to implement an existing sensor node employing both the MCU and the wireless communication module that features small size, low power consumption and low price. That is because the existing sensor node has power supplied to all of its modules even when some of the modules are needed to perform its functions, which leads to a high power consumption. Furthermore, the existing sensor node device requires an MCU to perform device control and application function. Hence, since the MCU and memory need to be incorporated in the sensor node device, it is difficult to implement a low-priced, small-sized sensor node device. Although the sensor node device with no MCU may implement desired application functions using some hardware, the hardware should be replaced to change its function or operation.

Accordingly, a new sensor node is required which features low price, small size and low power consumption and is capable of changing the operation of hardware without replacing the hardware.

### SUMMARY

The present invention provides a low-priced, small-sized and low-powered wireless sensor node which combines functional modules to perform specific functions without an extra processor to control a device. Furthermore, the present invention provides a wireless sensor node which minimizes power consumption by independently driving individual functional modules. In addition, the present invention provides a wireless sensor node which is operated under control of a remote control node without any processor and operating software.

The present invention provides a low-priced, small-sized and low-powered wireless sensor node which operates functional modules to cooperatively perform its individual functions without an extra processor to control operation of a device. Further, the present invention provides a wireless sensor node which minimizes power consumption by independently driving functional modules. In addition, the present invention provides a wireless sensor node which is independently operated under control of a remote control node with no processor and operating software.

In one general aspect, there is provided a wireless sensor node including at least one sensor, including: a wireless transceiver to wirelessly communicate with a control node; a primary configuration unit to set a node identification address in communication with the control node; a secondary configuration unit to cause the node identification address to be registered with the control node and to be assigned an address for communication from the control node using the node identification address; a plurality of functional modules to perform data processing and control the sensor; and a functional module activator to selectively activate the functional modules according to a type of received data or data to be transmitted.

The functional modules may include: a timer to operate in synchronization with a network reference clock; a data transceiver module to perform Cyclic Redundancy Checking (CRC) and determine if the received data is valid; a packet assembly/disassembly module to create a data packet to transmit or to extract information from a packet of the received data; a protocol processing module to check a format of the received data packet to determine a type of the received data; a random number generator to generate a random number for data transmission; a sensor control module to control the sensor; a sensor information processing module to process information acquired through the sensor; and a timestamp module to provide a clock sync reference.

The functional modules may further include: a standby module to wait for a predetermined time period; a security module to check if a received packet is secured; and a database module to store data therein.

The functional module activator may further activate the sensor control module and the sensor information processing module if the type of received data is sensor control data.

The secondary configuration unit may transmit a registration request message to the control node or responds to a registration command message from the control node to be assigned the address for communication.

Other features will become apparent to those skilled in the art from the following detailed description, which, taken in conjunction with the attached drawings, discloses exemplary embodiments of the invention.

### BRIEF DESCRIPTION OF THE DRAWINGS

FIG. 1 is a block diagram illustrating a wireless sensor node according to an exemplary embodiment of the present invention.

FIG. 2 is a flow chart illustrating the operation of a wireless sensor node according to an exemplary embodiment of the present invention.

FIG. 3 is a flow chart illustrating a primary configuration process in FIG. 2.

FIG. 4 is a flow chart illustrating a secondary configuration process in FIG. 2.

FIG. 5 is a flow chart illustrating the operation of a sensor node in a data receive mode.

FIG. 6 is a flow chart illustrating the operation of a sensor node in a data transmit mode.

Elements, features, and structures are denoted by the same reference numerals throughout the drawings and the detailed description, and the size and proportions of some elements may be exaggerated in the drawings for clarity and convenience.

### DETAILED DESCRIPTION

The following detailed description is provided to assist the reader in gaining a comprehensive understanding of the methods, apparatuses and/or systems described herein. Various changes, modifications, and equivalents of the systems, apparatuses and/or methods described herein will suggest themselves to those of ordinary skill in the art. Descriptions of well-known functions and structures are omitted to enhance clarity and conciseness.

An exemplary wireless sensor node has been designed to be divided into functional modules on a function basis and to operate the functional modules to cooperatively perform its individual functions.

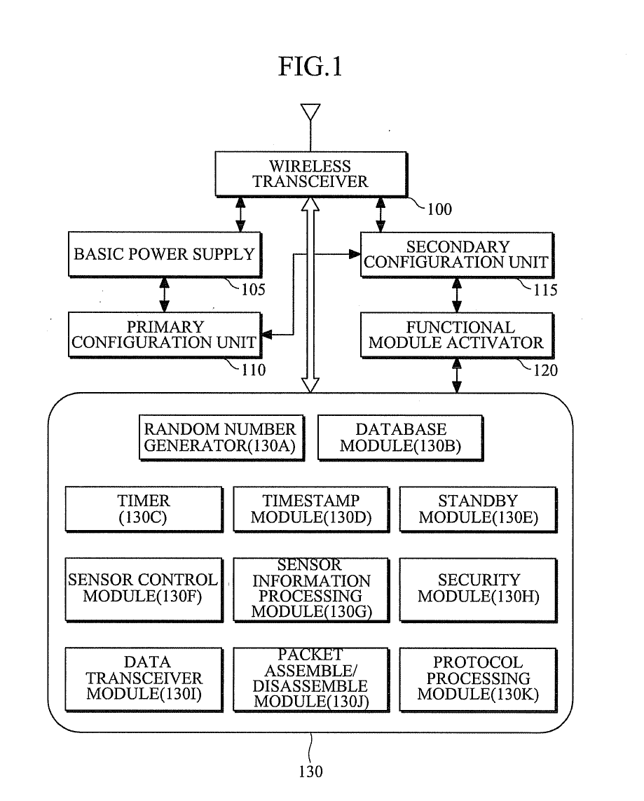

FIG. 1 is a block diagram illustrating a wireless sensor node according to an exemplary embodiment of the present invention.

The wireless sensor node includes a wireless transceiver 100, a primary configuration unit 110, a secondary configuration unit 115, a basic power supply 105, functional modules 130, and a functional module activator 120.

The wireless transceiver 100 wirelessly transmits and receives data to and from a control node at a remote location. The primary configuration unit 110 sets a node identification address, such as IEEE 64 bit address, in communication with the control node. The secondary configuration unit 115 uses the node identification address to register with the control node and sets a communication address assigned by the control node. The basic power supply 105 supplies power to modules for communication and sensor control. The functional modules 130 perform data processing and sensor control. The functional module activator 120 searches and activates a functional module according to a type of received data or a necessary operation for data transmission.

More specifically, the functional modules 130 further include a random number generator 130A to generate a random number necessary for data transmission, as shown in FIG. 1. The random number generator 130A provides a random number necessary for Carrier Sense Multiple Access with Collision Avoidance (CSMA/CA) which is widely used in mobile telecommunications. The functional modules 130 further include a timer 130C, a timestamp module 130D, a sensor control module 130F, a sensor information processing module 130G, a data transceiver module 130I, a packet assembly/disassembly module 130J, and a protocol processing module 130K. The timer 130C is operated in synchronization with a network reference clock. The timestamp module 130D provides a clock sync reference. The sensor control module 130F controls a sensor. The sensor information processing module 130G processes information acquired through a sensor. The data transceiver module 130I generates and checks a CRC and only receives a packet complying with a predetermined rules, i.e., determines validity of data. The packet assembly/disassembly module 130J makes a data packet to be transmitted or extracts information from a received data packet. The protocol processing module 130K checks a disassembled packet format to determine a type of received data.

In another embodiment, the functional modules 130 may further include a standby module 130E, which waits for a predetermined time period, a security module 130H, which checks security of a received packet like AES-CCM defined in IEEE 802.15.4 or the like, and a database module 130B, which stores sensor data or data received from the control node.

The protocol processing module 130K determines a data type from a predetermined bit in a packet format. According to the determination, the protocol processing module 130K sends data to one of the configuration units 110 and 115, the functional module activator 120, the sensor control module 130F and the database module 130B. If the data is determined by the protocol processing module 130K as sensor control data, the functional module activator 120 further activates the sensor control module 130F and the sensor information processing module 130G. Hence, since power is turned off prior to the activation, power consumption may be reduced. Similarly, the functional module activator 120 further activates the security module 130H only if necessary to check security of a packet. As will be described below, the secondary configuration unit 115 may send a registration request message to a control node or respond to a registration command message from the control node to be assigned the address for communication.

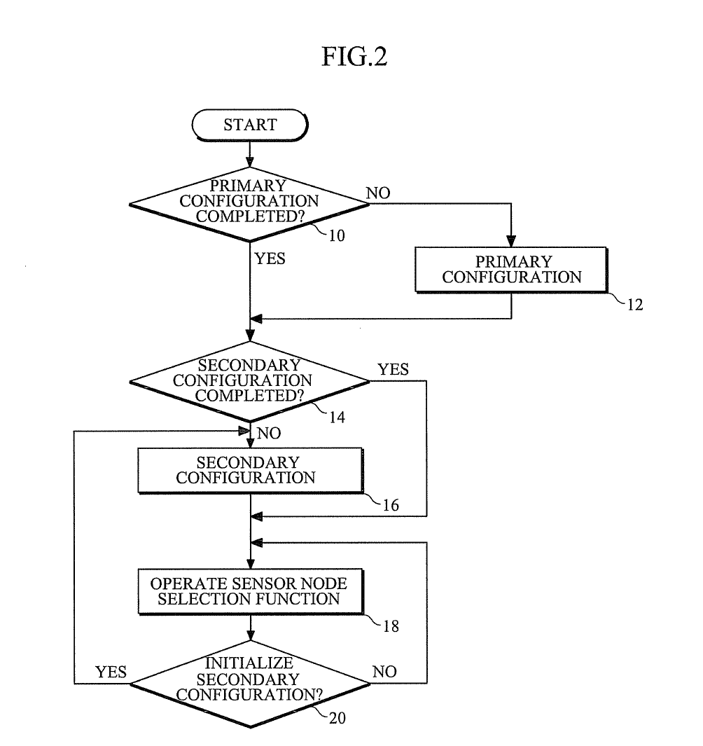

The operation of the wireless sensor node will be described in detail with reference to FIGS. 2 to 6.

FIG. 2 is a flow chart illustrating the operation of a wireless sensor node according to an exemplary embodiment of the present invention.

For the wireless sensor node to be normally operated, the wireless sensor node needs to perform two configuration processes in communication with the control node. More specifically, in operation 10, the wireless sensor node checks if a primary configuration has been completed. If completed, in operation 14, it checks if a secondary configuration has been completed. If not completed, in operation 12, it performs the primary configuration. The primary configuration is performed by the primary configuration unit 110, as described below.

The primary configuration is a process where a node identification address, such as IEEE 64 bit address, is set for one node, which is normally performed once after the sensor node has been released. Since it is for setting the node identification address, the configuration is basically performed for one node. In case of mass production, however, the configuration may be performed for a plurality of nodes, for example, with Carrier Sense Multiple Access with Collision Avoidance (CSMA/CA). Use of CSMA/CA requires a random number generator. In this case, since the same random number generator 130A is used for each node, the same random number may be generated. To avoid such a situation, the following may be used.

Firstly, after the sensor node is powered on to generate a random number, its random number generating function is maintained until the configuration is completed and a logical connection is completed. Actually, there is no chance that nodes will have the same initial operation starting time. Accordingly, if the sensor node is initially powered on and continues to generate random numbers, chances are negligible that the same random number will be generated. However, this method is disadvantageous in that continuous generation of the random numbers may cause a great deal of power consumption.

Alternatively, in order not to generate the same random number, different seeds are provided to have random features, which are used in the present invention.

The secondary configuration is a process where the sensor node is registered with the is control node using the node identification address which has been used in the primary configuration, and is assigned a communication address for communication by the control node. The secondary configuration needs to be performed by all nodes which have completed the primary configuration (i.e., have been assigned 64 bit node identification address).

Accordingly, if the primary configuration has been completed in operation 12, the wireless sensor node performs the secondary configuration in operations 14 and 16, and operates a sensor node selection function according to a type of data received from the control node in operation 18. The term sensor node selection function means that functions in the sensor node are selected (activated) and operated according to a type of data received from the control node. In operation 20, the wireless sensor node restarts the secondary configuration or repeats the sensor node selection function depending on whether the control node has requested initialization of the secondary configuration.

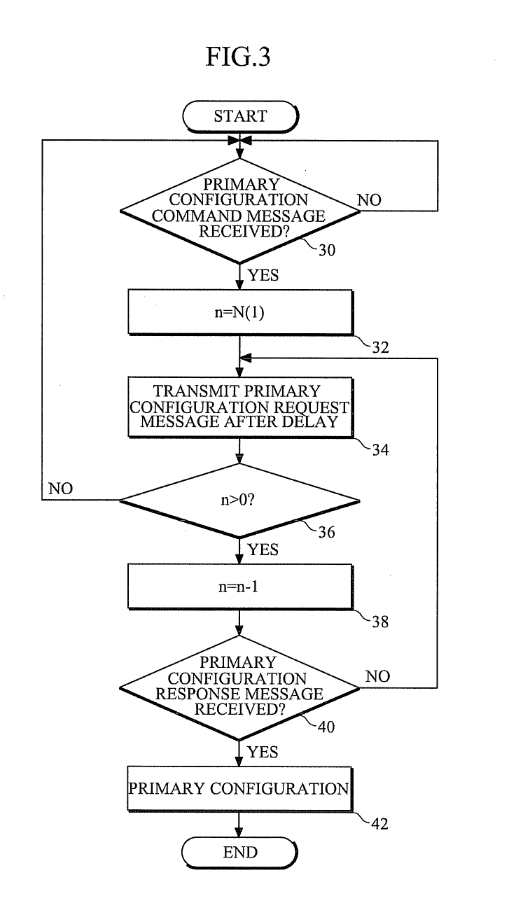

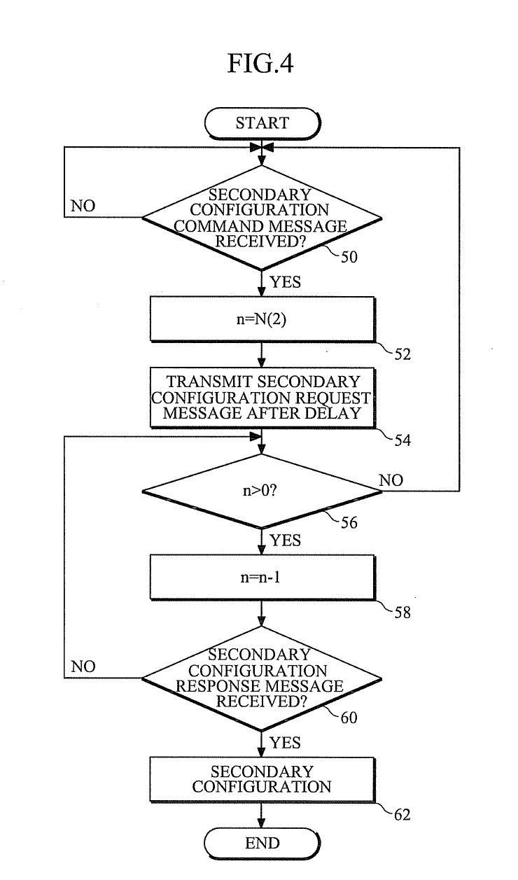

As described above with reference to FIG. 2, the wireless sensor node has sequentially completed the primary configuration and the secondary configuration and then normally operated the sensor node selection function. Methods of performing the primary and secondary configurations will now be described with reference to FIGS. 3 and 4, respectively.

FIG. 3 is a flow chart illustrating a primary configuration process in FIG. 2. The primary configuration uses “primary configuration command message”, “primary configuration request message” and “primary configuration response message”.

Referring to FIG. 3, the primary configuration command message, which is sent from the control node to the sensor node at regular intervals, is used to instruct a node, which has not completed the primary configuration, to complete the primary configuration. The primary configuration request message is used for the node, which has received the primary configuration command message, to request initialization from the control node. The primary configuration is response message is a message from the control node in response to the request of the sensor node. The three messages are used for the following operations.

If the sensor node is powered on, the primary configuration unit 110 checks primary configuration information. If the primary configuration has not yet been completed, in operation 30, the primary configuration unit 110 awaits the primary configuration command message. If the primary configuration command message is received, in operation 34, the primary configuration request message is transmitted after a predetermined delay according to CSMA/CA and awaits the response. For this operation, in operation 32, the primary configuration unit 110 initializes a value of n to N(1) and decreases the value of n by one (1) (i.e., n=n−1) while repeating operations 34 to 40 until the response is received. In operation 36, if the value of n becomes zero (0) and no response is received until a predetermined time period elapses, the process proceeds back to operation 30 where the primary configuration unit 110 awaits the primary configuration command message.

If the primary configuration continuously failed more than a predetermined times and the primary configuration command message is received, the primary configuration request message is transmitted after a predetermined minimum delay necessary at least for collision avoidance even though an expected time period has not yet elapsed. The primary configuration request message sends a certain value generated by itself to its own ID. The primary configuration response message is sent to the ID which uses the primary configuration request message. Nodes with the same ID start to perform the primary configuration process. If two or more nodes attempt to perform the primary configuration process, the control node sends an error message and restarts the process after the minimum delay. An essential part of the primary configuration process is to store unique information at a predetermined position of a node with a remote control message. In this case, a memory which maintains a value even after power-off is generally used. If a memory which does not maintain a value after power-off is used, the configuration needs to be restarted whenever the power is turned on.

Through the process above, the primary configuration unit 110 sets the node identification address.

FIG. 4 is a flow chart illustrating a secondary configuration process in FIG. 2.

Referring to FIG. 4, in operation 50, the secondary configuration unit 115 checks if the secondary configuration command message has been received from the control node. If the secondary configuration command message is received, in operation 52, a counter n, which is used in awaiting the secondary configuration response message, is initialized to N(2) and, in operation 54, sends the secondary configuration request message. It decreases the value of n by one (1) (i.e., n=n−1) while repeating operations 56 to 60 until the response is received. If the secondary configuration response message is received, in operation 62, it performs the secondary configuration. If not received, the process proceeds back to the operation of receiving the secondary configuration command message.

All nodes are allowed to access a desired network after they are permitted by a control node which controls the network. Accordingly, all of the sensor nodes are subject to registration with the control node and are assigned addresses (i.e., communication addresses for communication) after the registration. Such a registration process is the above-mentioned secondary configuration where the assigned address is a 16 bit address, for example, in IEEE 802.15.4-2006.

If a sensor node has not been registered with the control node, the sensor node's secondary configuration unit may send a registration request message (corresponding to the secondary configuration request message) to the control node or respond to a registration command message (corresponding to the secondary configuration command message) from the control node to be assigned the communication address. The sensor node uses the address assigned in the primary configuration until it is assigned the communication address, while it uses the communication address after the registration with the control node.

After registration, the sensor node makes a communication at regular intervals which have been determined in the registration process, regardless of whether data has been received or not. If the communication is not made at the regular intervals, the registered connection is considered failed and the registration process needs to be performed. The connection failure may be determined based on a predetermined criterion. In this process, if the node registration and the ID assigning process are determined as 16 bit ID is set in IEEE 802.15.4-2006, the method in FIG. 4 as well as the existing method may be used.

In short, the primary and secondary configuration units 110 and 115 set the node identification address in communication with the control node, register the sensor node with the control node using the node identification node, set the communication node assigned by the control node, and make a communication using the communication node.

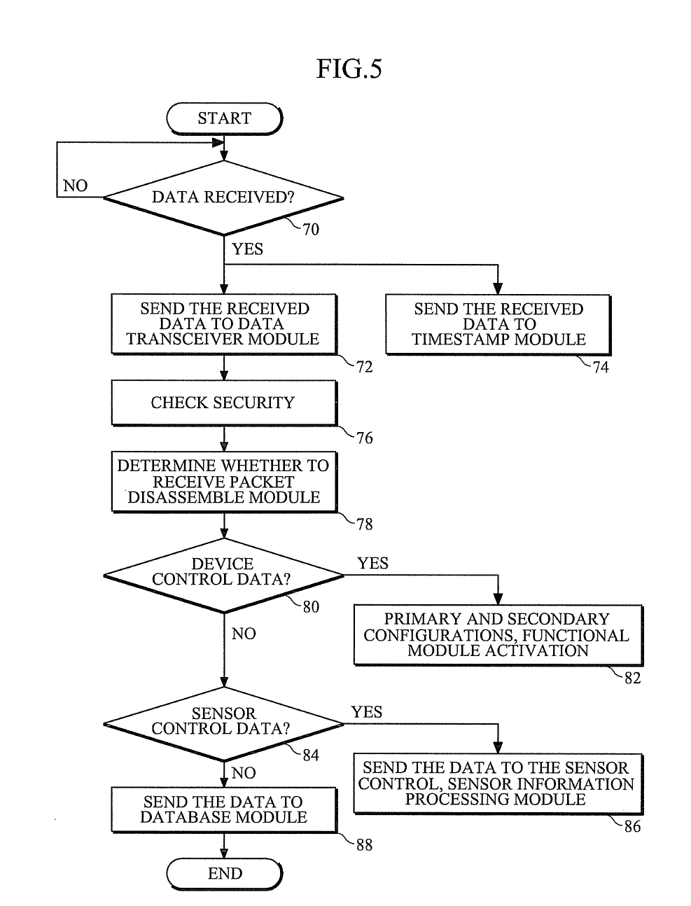

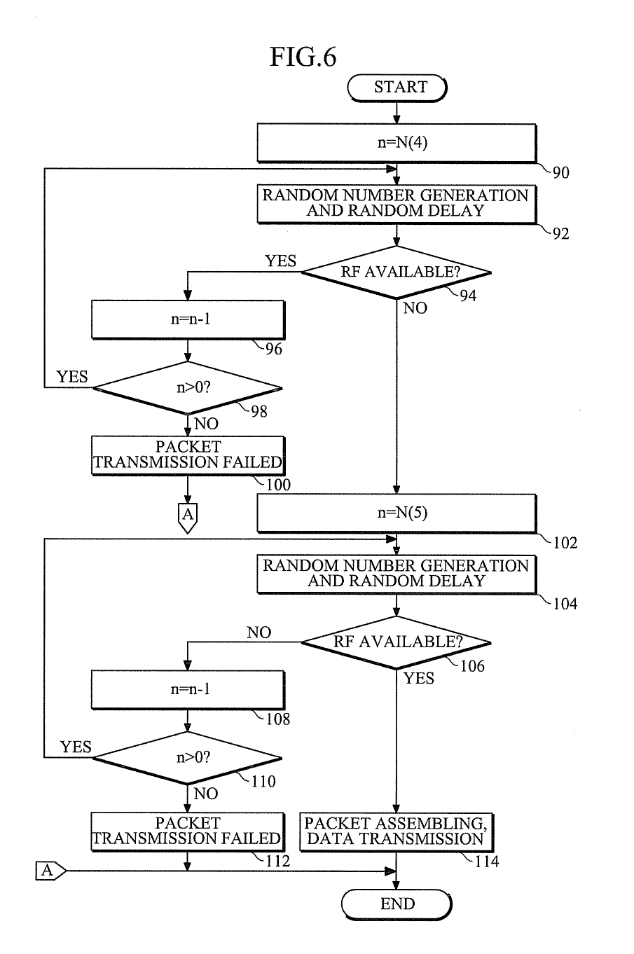

The primary and secondary configuration processes will now be described with reference to FIGS. 5 and 6.

FIG. 5 is a flow chart illustrating the operation of a sensor node in a data receive mode.

Referring to FIG. 5, if the sensor node is powered on, power is supplied to some functional modules necessary for processing communication and received data by means of the to basic power supply 105 and the functional module activator 120. In operation 70, if data is received from the control node through the wireless transceiver 100, the data is forwarded to the data transceiver module 130I and the timestamp module 130D. The data transceiver module 130I checks a CRC of a received packet to determine if it is valid data. If it is valid, the data transceiver module 130I sends the packet to the security module 130H. In operation 76, the security module 130H checks security of the packet. In operation 78, the packet assembly/disassembly module 130J determines whether to discard or receive the secured packet.

If the packet is determined to be received, the protocol processing module 130K determines a type of the data. The protocol processing module 130K may determine the data type depending on whether a specific bit in a packet format is set. More specifically, if the data is device control data for requesting the primary or secondary configuration, in operation 82, the protocol processing module 130K forwards the data to the functional module activator 120 and the primary or secondary configuration unit 110 or 115. The functional module activator 120 activates the primary or secondary configuration unit 110 or 115 and some functional modules necessary for each configuration unit to make a request for messages.

In short, the initialization of the sensor node and the registration of the control node are completed by driving the configuration units 110 and 115 activated by the functional module activator 120 according to the method described with reference to FIG. 3 or 4. In this case, since functional modules unnecessary for this process, such as the sensor control module 130F and the sensor information processing module 130G, are not activated, it is possible to reduce the power consumption.

In operation 84, if the data is sensor control data, in operation 86, the data is sent to the sensor control module 130F and the sensor information processing module 130G through the protocol processing module 130K. In this case, the sensor control module 130F and the sensor information processing module 130G are activated by the functional module activator 120 so that the sensor control data may be processed.

If the data is not the device control data or the sensor control data, in operation 86, the protocol processing module 130K sends the data to the database module so that the data may be stored in the database module.

Accordingly, since the functional modules of the sensor node are activated according to the data type, the sensor node may process the data using on a functional module basis without a processor such as an MCU.

FIG. 6 is a flow chart illustrating the operation of a sensor node in a data transmit mode.

A message to be transmitted to the control node in the primary or secondary configuration upon request is transmitted according to the process in FIG. 6. The wireless sensor node employs CSMA/CA to transmit packets. In this case, the sensor node is generally subject to delay processes (operations 92 and 104). More specifically, the functional module activator 120 activates the random number generator 130A and the standby module 130E for data packet transmission and delay. The random number generator 130A generates a random number for data packet transmission. After a predetermined delay by the standby module 130E, in operations 94 and 106, the sensor node checks if an RF resource is available. If the RF resource is not available, the sensor node repeatedly checks the availability of the RF resource N(4) or N(5) times. If the RF resource is still not available even after the repetitive attempts, the transmission is considered failed. On the contrary, if successful, the functional module activator 120 activates the packet assembly/disassembly module 130J and the data transceiver module 130I so that the data may be formed into data packets and transmitted in operation 114.

Accordingly, the wireless sensor node may normally transmit the data packets to the control node.

Apparent from the above description, by dividing the sensor node into functional modules and selectively activating the functional modules according to a type of data received from the remote control node, it is possible to implement a low-powered sensor node. Further, by designing segmented blocks for performing the functions of the sensor node into hardware modules and activating the modules, no extra processor or memory for software for executing functions is needed. Accordingly, it is possible to implement a low-priced, small-sized wireless sensor node. In addition, since the address of the sensor node is set upon request of the remote control node, the installation and maintenance of the sensor node are facilitated.

Furthermore, since the operational characteristic of each hardware block may be changed according to the data received from the remote control node, there is no need to replace hardware chips to change the functional and operational characteristics of the hardware.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A wireless sensor node including at least one sensor, comprising:
a wireless transceiver to wirelessly communicate with a control node;
a primary configuration unit to set a node identification address in communication with the control node;
a secondary configuration unit to cause the node identification address to be registered with the control node and to be assigned an address for communication from the control node using the node identification address;
to a plurality of functional modules to perform data processing and control the sensor; and
a functional module activator to selectively activate the functional modules according to a type of received data or data to be transmitted.

2. The wireless sensor node of claim 1, wherein the functional modules comprise:
a timer to operate in synchronization with a network reference clock;
a data transceiver module to perform Cyclic Redundancy Checking (CRC) and determine if the received data is valid;
a packet assembly/disassembly module to create a data packet to transmit or to extract information from a packet of the received data;
a protocol processing module to check a format of the received data packet to determine a type of the received data;
a random number generator to generate a random number for data transmission;
a sensor control module to control the sensor;
a sensor information processing module to process information acquired through the sensor; and
a timestamp module to provide a clock sync reference.

3. The wireless sensor node of claim 2, wherein the functional modules further comprise:
a standby module to wait for a predetermined time period;
a security module to check if the received packet is secured; and
a database module to store data therein.

4. The wireless sensor node of claim 2, wherein the protocol processing module transmits the received data to one of the primary configuration unit, the secondary configuration unit, the functional module activator and the sensor control module, according to the determined type of received data.

5. The wireless sensor node of claim 3, wherein the functional module activator further activates the sensor control module and the sensor information processing module if the type of received data is sensor control data.

6. The wireless sensor node of claim 5, wherein the functional module activator further activates the security module to check if the received data packet is secured.

7. The wireless sensor node of claim 1, wherein the secondary configuration unit transmits a registration request message to the control node or responds to a registration command message from the control node to be assigned the address for communication.

8. A method of controlling a wireless sensor node to perform data processing and sensor control in communication with a control node, the method comprising:
setting a node identification address in communication with the control node;
being assigned an address for communication from the control node using the node identification address; and
selectively activating the functional modules according to a type of received data or data to be transmitted.

9. The method of claim 8, wherein the setting of the node identification address comprises:
transmitting, if a registration command message for the node identification address is received from the control node, a registration request message after a predetermined delay necessary at least for collision avoidance elapses.
setting, if a response message is received in response to the registration request message, the node identification address;
retransmitting, if no response message is received in response to the registration request message, the registration request message; and
awaiting, if no response message is received until a predetermined time period elapses, a registration command message for the node identification address from the control node.

10. The method of claim 8, wherein the being assigned of the address for communication comprises:
transmitting, if a registration command message for the address for communication is received from the control node, a registration request message after a predetermined delay necessary at least for collision avoidance elapses;
setting, if a response message for the registration request message is received, the address for communication; and
awaiting, if no response message is received until a predetermined time period elapses, a response message from the control node.

11. A method of controlling a wireless sensor node to perform data processing and sensor control in communication with a control node, the method comprising:
performing, if a data packet is received from the control node, Cyclic Redundancy Checking (CRC) on the data packet to determine if the data packet is valid;
if the data packet is valid, checking whether the data packet is secured, and if the data packet is secured, determining whether to discard or receive the data packet;
checking, if the result of the determination is to receive the data packet, a format of the data packet to determine a type of the data packet; and
activating a necessary function according to the determined type of the data packet.
